(19) United States
(12) Patent Application Publication
(10) Pub. No.: US 2007/0131985 A1
(43) Pub. Date: Jun. 14, 2007

(54) Semiconductor device and method for manufacturing the same

(76) Inventors: Kazunori Fujita, Yoro-Gun (JP); Yoshikazu Yamaoka, Ogaki-shi (JP); Satoru Shimada, Hashima city (JP); Hideki Mizuhara, Ichinomiya-city (JP); Yasunori Inoue, Ogaki-shi (JP)

Correspondence Address: MCDERMOTT WILL & EMERY LLP, 600 13TH STREET, N.W., WASHINGTON, DC, 20005-3096, US

(21) Appl. No.: 11/605,485

(22) Filed: Nov. 29, 2006

(30) Foreign Application Priority Data
Nov. 29, 2005 (JP) 2005-344585
Jan. 31, 2006 (JP) 2006-023506
Jan. 31, 2006 (JP) 2006-023834

(51) Int. Cl. H01L 29/76

(52) U.S. Cl. 257/288

(57) ABSTRACT

A semiconductor device and a method for manufacturing the same are provided, in which the work function of a gate electrode being in contact with a gate insulating film can be efficiently adjusted while depletion of the gate electrode is suppressed. An SOI substrate is composed of a p-type silicon substrate, a buried oxide film, and a single crystal silicon layer. Furthermore, source and drain regions are provided in the single crystal silicon layer. In the single crystal silicon layer, the surface between the source and drain regions serves as a channel layer. A gate insulating film is formed on the single crystal silicon layer (the channel layer). On the gate insulating film is provided a polysilicon gate electrode composed of metal particles of TiN and a polysilicon film. The metal particles of TiN include particles being in contact with the gate insulating film and particles being out of contact with this film.

### BACKGROUND OF THE INVENTION

1. Field of the Invention

The present invention relates to a semiconductor device and a method for manufacturing the same. In particular, the invention relates to a semiconductor device having particulate metal between a gate insulating film and a gate electrode and to a method for manufacturing the same.

2. Description of the Related Art

In recent years, in order to increase the speed of semiconductor devices and to reduce the power consumption thereof, the gate length of transistor gate electrodes and gate insulating film thickness have been reduced, and high dielectric constant gate insulating films have been developed. In a conventional polycrystalline silicon gate electrode for a transistor which employs impurity-doped polycrystalline silicon (polysilicon) as a gate electrode material, even when the thickness of the gate insulating film of the transistor is reduced, the effect of the thickness reduction is not reflected on the effective thickness of the gate insulating film. This is because the polycrystalline silicon gate electrode is depleted in the proximity of the gate insulating film. Therefore, the employment of a metal gate electrode, which uses a metal as the material for the gate electrode, has been considered (see Japanese Patent Laid-Open Publication No. Hei 11-224947). When such a metal gate electrode is employed, the problem of depletion in the gate electrode can be avoided. However, a problem arises in that it is difficult to adjust the work function (to control the threshold voltage) of the gate electrode because pinning occurs.

A method as described in Extended Abstracts of the 2004 International Conference on Solid State Devices and Materials (Sep. 15, 2004, p 488-489) may be employed to solve the foregoing problem. FIG. 17 is an enlarged cross-sectional view illustrating a gate electrode portion of a field effect type MOS transistor described in this publication.

In this field effect type MOS transistor, the gate electrode portion is configured to include a gate insulating film 102 provided on a silicon substrate 101 and a polysilicon gate electrode 105. The polysilicon gate electrode 105 is composed of polysilicon 104 and metal particles (metal dots) 103 which are formed of tantalum nitride (TaN) and are provided on the gate insulating film 102. By introducing the metal dots 103 of TaN on the interface between the polysilicon gate electrode 105 and the gate insulating film 102 as described above, adjustment of the work function (control of the threshold voltage) of the gate electrode 105 can be achieved, and depletion can be suppressed.

In the conventional method, the metal dots 103 are disposed so as to contact the gate insulating film 102. With this arrangement, the effective work function of the metal dots 103 is shifted to the mid-gap of silicon (Si) after heat treatment such as activation annealing, causing a shift in the work function (a shift in the threshold voltage) of the gate electrode 105.

Furthermore, in the conventional method, the metal dots 103 contacting the gate insulating film 102 are disposed two-dimensionally. Thus, when the metal dots 103 are disposed at high density, the ratio of the polysilicon 104 contacting the gate insulating film 102 between the metal dots 103 becomes low. Hence, a problem may arise in that it is difficult to adjust the work function (to control the threshold voltage) of the gate electrode 105 with an impurity in the polysilicon 104. Furthermore, as the ratio of the metal dots 103 contacting the gate insulating film 102 becomes large, the adjustment of the work function of the gate electrode 105 is strongly affected by a phenomenon in which the Fermi level of the metal dots is shifted to the mid gap of silicon (Si). This phenomenon is believed to occur because of an interface reaction between the metal dots 103 and the gate insulating film 102. Hence, the work function of the gate electrode 105 becomes more difficult to adjust. Therefore, in the conventional method, a predetermined spacing must be provided between the metal dots, and thus depletion in the polysilicon between the metal dots cannot be suppressed effectively. Furthermore, there is a demand for further improvements to the performance of a conventional field effect type MOS transistor having metal dots.

### SUMMARY OF THE INVENTION

The present invention has been made in view of the foregoing circumstances. A general purpose of the invention is to provide a semiconductor device in which the work function of a polysilicon gate electrode contacting a gate insulating film can be adjusted, while depletion in the polysilicon gate electrode is suppressed, and to provide a method for manufacturing the same. Another general purpose of the invention is to provide a semiconductor device which has metal particles between a gate insulating film and a gate electrode, and to provide a method for manufacturing the same. In this semiconductor device, adjustment of the work function (control of the threshold voltage) of the gate electrode can be achieved, and depletion in the gate electrode can be suppressed. In addition, the adhesive properties of the metal particles are improved. Still another general purpose of the invention is to provide a semiconductor device in which the work function of a gate electrode can be efficiently adjusted, while depletion in the gate electrode contacting a gate insulating film is suppressed, and to provide a method for manufacturing the same.

In order to achieve the foregoing general purpose, one embodiment of the present invention relates to a semiconductor device including: a semiconductor substrate having a principal surface; a channel region which is provided in the principal surface of the semiconductor substrate; an insulating layer which is provided on the channel region; and a semiconductor layer which is provided on the insulating layer. In the semiconductor device, the semiconductor layer contains a plurality of first metal particles disposed in a lower region of the semiconductor layer, and the first metal particles are out of contact with the insulating layer.

In this configuration, depletion in the proximity of the interface between the semiconductor layer and the insulating layer can be suppressed by the supply of carriers from the first metal particles. Therefore, a high performance semiconductor device can be provided. Furthermore, since the semiconductor layer intervenes between the first metal particles and the insulating layer, the first metal particles are not in direct contact with the insulating layer. Accordingly, Fermi level pinning of the first metal particles does not occur, and a shift in the work function (a shift in the threshold voltage) of the semiconductor layer does not occur. Hence, adjustment of the work function (control of the threshold voltage) of the semiconductor layer can easily be achieved. Moreover, since the effect of suppressing depletion in the semiconductor layer is achieved in a region below the first metal particles, depletion in the semiconductor layer can be suppressed, as compared to a conventional case in which first metal particles contact an insulating layer.

Accordingly, a semiconductor device can be provided in which adjustment of the work function (control of the threshold voltage) of the semiconductor layer can be achieved while depletion in the semiconductor layer provided on the insulating layer is suppressed.

In another embodiment of the present invention, the semiconductor layer further comprises therein a plurality of second metal particles being in contact with the insulating layer. In this configuration, depletion in the proximity of the interface between the semiconductor layer and the insulating layer can be suppressed by the supply of carriers from the first and second metal particles. Therefore, a high performance semiconductor device can be provided. In particular, since the semiconductor layer includes the second metal particles being in contact with the insulating layer, the effect of suppressing depletion is achieved not only in a region below the first metal particles but also in a region alongside the side surface of the second metal particles. Therefore, depletion in the semiconductor layer can be suppressed more efficiently in the proximity of the first and second metal particles, as compared to a conventional case in which a semiconductor layer includes only second particles contacting an insulating layer.

Furthermore, the second metal particles are in contact with the insulating layer as described above. Thus, in this portion, a phenomenon occurs in which the effective work function of the second metal particles is shifted to the mid-gap of silicon (Si) when heat treatment is performed. In this case, a shift in the effective work function (a shift in the threshold voltage) of the semiconductor layer occurs in the proximity of the second metal particles. However, the first metal particles are out of contact with the insulating layer. Thus, in the proximity of the first metal particles, the work function of the semiconductor layer is not affected by the first metal particles. Hence, the semiconductor layer is determined. Thus, by adjusting the ratio of the first metal particles to the second metal particles in the semiconductor layer, adjustment of the work function (control of the threshold voltage) of the semiconductor layer can be achieved.

Accordingly, a semiconductor device can be provided in which adjustment of the work function (control of the threshold voltage) of the semiconductor layer can be achieved while depletion in the semiconductor layer provided on the insulating layer is suppressed.

In still another embodiment of the present invention, the spacing between adjacent second metal particles is smaller than a size of the second metal particles, and at least some of the first metal particles have a size the same as that of the second metal particles and are disposed via a portion of the semiconductor layer which is between the adjacent second metal particles. In this manner, the portion of the semiconductor layer which is between adjacent second metal particles to is surrounded three-dimensionally by the side surface of the second metal particles and the lower surface of the first metal particles, whereby depletion in the semiconductor layer can be effectively suppressed.

In the above configuration, it is preferable that the first and second metal particles be arranged two-dimensionally in a lower region of the semiconductor layer. In this manner, the effect of suppressing depletion in the semiconductor layer is homogenized, and thus a semiconductor device with less performance variation can be provided.

Furthermore, in the above configuration, it is preferable that the semiconductor layer contain an impurity of a predetermined conduction type and that the impurity be introduced into the semiconductor layer by implantation. In this manner, the impurity can be easily introduced into the proximity of a portion of the semiconductor layer which is in contact with the insulating layer. Thus, the impurity not only provides the effect of suppressing depletion but also allows the work function of the semiconductor layer to be adjusted. In particular, since the impurity can also be introduced into a portion of the semiconductor layer which is located under the first metal particles, depletion in the semiconductor layer can be suppressed more effectively.

In order to achieve the foregoing general purpose, another embodiment of the present invention relates to a method for manufacturing a semiconductor device, comprising: a first step of forming an insulating layer on a channel region provided on a principal surface of a semiconductor substrate; a second step of forming a first semiconductor layer into a pattern of dots on the insulating layer; a third step of forming a plurality of metal particles on the insulating layer and the first semiconductor layer; a fourth step of forming a second semiconductor layer on the first semiconductor layer and the metal particles; and a fifth step of forming an electrode by processing the insulating layer, the first semiconductor layer, and the second semiconductor layer. In the method, the metal particles formed in the third step are composed of first metal particles formed on the first semiconductor layer and second metal particles formed on the insulating layer.

According to the above manufacturing method, the electrode can be composed of the semiconductor layers (the first and second semiconductor layers) containing the first metal particles and the second metal particles. The first metal particles are formed such that the first semiconductor layer intervenes between the first metal particles and the insulating layer, and the second metal particles are in contact with the insulating layer. Thus, a high performance semiconductor device can be manufactured in which depletion in the proximity of the interface between the semiconductor layer and the insulating layer can be suppressed by the supply of carriers from the metal particles. Moreover, by controlling the formation ratio of the first semiconductor layer formed into a pattern of dots in the second step, the final ratio of the first metal particles to the second metal particles in the electrode can be adjusted. Thus, adjustment of the work function (control of the threshold voltage) of the electrode can easily be achieved. Furthermore, since the metal particles including the first and second metal particles can be formed in a single process, the manufacturing cost of the semiconductor device can be reduced.

In order to achieve the other general purpose described above, still another embodiment of the present invention relates to a semiconductor device, including: a semiconductor substrate having a principal surface; a channel region provided in the principal surface of the semiconductor substrate; an insulating layer provided on the channel region; and a semiconductor layer provided on the insulating layer. In the semiconductor device, the semiconductor layer contains a plurality of metal particles disposed in a lower region of the semiconductor layer, and a first reaction layer formed through reaction with the semiconductor layer is provided on the surface of the metal particles.

In the above configuration, the metal particles are physically bonded to the semiconductor layer through chemical bonding with the first reaction layer. Hence, the bonding strength between the metal particles and the semiconductor layer is enhanced. Thus, the adhesive properties between the metal particles and the semiconductor layer are improved, and the reliability of the semiconductor device is improved. Furthermore, in the semiconductor layer having the above configuration, since carriers (charges) are supplied from the metal particles to the semiconductor layer through the first reaction layer, depletion can be suppressed in the proximity of the interface between the semiconductor layer and the insulating layer. Moreover, the contact area between the metal particles and the insulating layer can be reduced as compared with the case of a conventional metal gate electrode. Accordingly, the shift of the effective work function occurring in the proximity of the metal particle/insulating layer interface is less likely to occur. Hence, adjustment of the work function (control of the threshold voltage) of the semiconductor layer can be more easily achieved as compared with a conventional metal gate electrode. Therefore, a semiconductor device can be provided in which depletion can be suppressed and adjustment of the work function (control of the threshold voltage) of the semiconductor layer can be achieved, and in which also the adhesion properties of the metal particles are improved.

In still another embodiment of the present invention, some of the metal particles are arranged so as to be in contact with the insulating layer, and a second reaction layer formed through reaction with the insulating layer is provided in the proximity of an interface between the metal particles and the insulating layer. In this configuration, the effects described above can be achieved. In addition, since the metal particles are physically bonded to the insulating layer through chemical bonding with the second reaction layer, the bonding strength between the metal particles and the insulating layer is enhanced, and the adhesion properties between the metal particles and the insulating layer are improved. Thus, the reliability of the semiconductor device is further improved.

In the above configuration, it is preferable that the semiconductor layer be formed of a film containing silicon and that the first reaction layer be formed of a metal silicide. With this configuration, the semiconductor layer is electrically connected to the metal particles through the first reaction layer (metal silicide), which is formed through reaction of the metal atoms contained in the metal particles with the silicon atoms contained in the semiconductor layer. Thus, the electrical resistance between the semiconductor layer and the metal particles is reduced. Hence, carrier supply from the metal particles to the semiconductor layer is facilitated, and thus the effect of suppressing depletion in the semiconductor layer can be enhanced, which effect is obtained by providing the metal particles in the proximity of the insulating layer.

Furthermore, in the above configuration, it is desirable that the metal particles be formed of a metal nitride and that the ratio of the metal atoms forming the metal nitride be higher than the ratio of the nitrogen atoms forming the metal nitride. In this manner, a silicide reaction between the excess metal atoms on the surface of the metal particles and the silicon atoms contained in the semiconductor layer or the insulating layer occurs at a heat treatment temperature lower than a temperature conventionally employed, whereby the metal silicide can be provided. Hence, the adhesive properties between the metal particles and the semiconductor layer or between the metal particles and the insulating layer can be improved, and thus a semiconductor device having improved reliability can be provided.

In order to achieve the other general purpose described above, still another embodiment of the present invention relates to a method for manufacturing a semiconductor device, including: a first step of forming an insulating layer on a channel region provided in a principal surface of a semiconductor substrate; a second step of forming metal particles on the insulating layer; a third step of forming a semiconductor layer on the insulating layer and the metal particles; and a fourth step of forming an electrode by processing the insulating layer and the semiconductor layer. The method further includes a fifth step of forming a reaction layer on a surface of the metal particles by means of heat treatment, the fifth step being provided either or both before and after the fourth step.

With this method, the metal particles are allowed to react with the semiconductor layer during the heat treatment, whereby the reaction layer can easily be provided. Therefore, additional facility investment is not required, and a semiconductor device having improved reliability can be provided at low cost.

In order to achieve still another general purpose described above, another embodiment of the present invention relates to a semiconductor device, including: a semiconductor substrate; a channel region provided in a principal surface of the semiconductor substrate; an insulating layer provided on the channel region; and a semiconductor layer provided on the insulating layer. In the semiconductor device, the semiconductor layer contains a metal portion disposed in a lower region of the semiconductor layer, and the metal portion is out of contact with the insulating layer.

According to the above configuration, a semiconductor device can be provided in which adjustment of the work function (control of the threshold voltage) of the semiconductor layer can be achieved while depletion in the semiconductor layer provided on the insulating layer is suppressed. Specifically, in the semiconductor layer having the above configuration, depletion in the proximity of the interface between the insulating layer and the semiconductor layer below the metal portion can be suppressed by carrier supply from the metal portion. In addition, since the semiconductor layer intervenes between the metal portion and the insulating layer, the metal portion is not in direct contact with the insulating layer. Therefore, the effective work function shift, which would occur on the metal portion side in the proximity of the metal/insulating layer interface, does not occur. Thus, a shift in the work function (a shift in the threshold voltage) of the electrode formed by the semiconductor layer does not occur. Hence, adjustment of the work function (control of the threshold voltage) of the semiconductor layer can more easily be achieved as compared with a conventional metal gate electrode which is in direct contact with an insulating layer.

In the above configuration, it is preferable that the metal portion be formed of a plurality of first metal particles. In this manner, carriers are supplied from the first metal particles, whereby the effect of suppressing depletion in the semiconductor layer can be achieved in a region below the first metal particles and in a region alongside the side surface of the first metal particles. That is, in this configuration, the effect of suppressing depletion in the semiconductor layer can be enhanced by the first metal particles, which is not in contact with the insulating layer, without causing a shift in the effective work function (a shift in the threshold voltage) of the electrode. Thus, a high performance semiconductor device can be provided.

In another embodiment of the present invention, the semiconductor layer further contains a plurality of second metal particles disposed in a lower region of the metal portion and being in contact with the insulating layer, and at least some of the first metal particles are disposed via a portion of the semiconductor layer which is between the adjacent second metal particles. In this manner, carriers are also supplied from the side surface of the second metal particles to the portion of the semiconductor layer which is between the adjacent second metal particles. Hence, depletion in the proximity of the interface between the semiconductor layer and the insulating layer can be suppressed by the carriers supplied from the lower portion of the first metal particles and also from the side surface of the second metal particles. Thus, a semiconductor device can be provided in which depletion of the semiconductor layer is further suppressed.

In the above configuration, it is preferable that the semiconductor layer contain an impurity of a predetermined conduction type and that the impurity be introduced into the semiconductor layer by implantation. In this manner, the impurity can be easily introduced into the proximity of a portion of the semiconductor layer which is in contact with the insulating layer. Thus, the impurity not only provides the effect of suppressing depletion but also allows the work function of the semiconductor layer to be adjusted. In particular, since the impurity can also be introduced into a portion of the semiconductor layer which is located below the first metal particles, depletion in the semiconductor layer can be suppressed more effectively.

In still another embodiment of the invention, the metal portion is composed of a thin metal film. In this case, the effects achieved in the embodiment described above can also be achieved. In addition, for example, ion channeling (implantation of an impurity into the channel region) can be suppressed through the thin metal film at the time of introducing the impurity by means of ion implantation during manufacturing. Thus, the characteristics of the transistor can be stabilized. Furthermore, after the ion implantation, the impurity concentration in the semiconductor layer changes abruptly at the thin metal film (that is, the impurity is not implanted into the first semiconductor). Hence, during subsequent heat treatment for impurity diffusion, the impurity is allowed to diffuse uniformly from the thin metal film into the portion of the semiconductor layer which is located below the thin metal film, and thus the impurity concentration in the semiconductor layer can be easily controlled. Therefore, a semiconductor device having transistor characteristics with less performance variation can be provided.

In the above configuration, it is preferable that a thickness of the semiconductor layer between the metal portion and the insulating layer be 3 nm or less. In this manner, carriers are efficiently supplied from the metal portion to the bottom portion of the semiconductor layer below (the proximity of the insulating layer), and thus depletion in the proximity of the interface between the semiconductor layer and the insulating layer can be reliably suppressed. Thus, a high performance semiconductor device can be provided.

In order to achieve still another general purpose, one embodiment of the present invention relates to a method for manufacturing a semiconductor device, comprising: a first step of forming an insulating layer on a channel region provided on a principal surface of a semiconductor substrate; a second step of forming a first semiconductor layer into a pattern of dots on the insulating layer; a third step of forming a plurality of metal particles on the insulating layer and the first semiconductor layer; a fourth step of forming a second semiconductor layer on the first semiconductor layer and the metal particles; and a fifth step of forming an electrode by processing the insulating layer, the first semiconductor layer, and the second semiconductor layer. In the method, the metal particles formed in the third step are composed of first metal particles formed on the first semiconductor layer and second metal particles formed on the insulating layer.

According to the above manufacturing method, an electrode can be formed which is composed of the semiconductor layers (the first and second semiconductor layers) containing the first metal particles. Furthermore, the first semiconductor layer intervenes between the metal particles and the insulating layer. Thus, a semiconductor device can be manufactured in which depletion in the proximity of the interface between the first semiconductor layer and the insulating layer can be suppressed by the supply of carriers from the first metal particles without causing a shift in the effective work function (a shift in the threshold voltage) of the electrode. Moreover, by controlling the formation ratio of the first semiconductor layer formed into a pattern of dots in the second step, the final ratio of the first metal particles to the second metal particles in the electrode can be adjusted. Thus, adjustment of the work function (control of the threshold voltage) of the electrode can be achieved more effectively as compared with the case in which a conventional metal gate electrode is employed. Furthermore, since the metal particles including the first and second metal particles can be formed in a single process, the manufacturing cost of the semiconductor device can be reduced.

It is to be noted that any arbitrary combination or rearrangement of the above-described structural components and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a cross-sectional view of a field effect type transistor according to a first embodiment of the present invention;

FIG. 2 is a cross-sectional view illustrating a manufacturing process of the field effect type transistor according to the first embodiment of the present invention;

FIG. 3 is a cross-sectional view illustrating the manufacturing process of the field effect type transistor according to the first embodiment of the present invention;

FIG. 4 is a cross-sectional view illustrating the manufacturing process of the field effect type transistor according to the first embodiment of the present invention;

FIG. 5 is a cross-sectional view illustrating the manufacturing process of the field effect type transistor according to the first embodiment of the present invention;

FIG. 6 is a cross-sectional view illustrating the manufacturing process of the field effect type transistor according to the first embodiment of the present invention;

FIG. 7 is a cross-sectional view illustrating the manufacturing process of the field effect type transistor according to the first embodiment of the present invention;

FIG. 8 is a cross-sectional view of a field effect type transistor according to a second embodiment of the present invention;

FIG. 9 is a series of schematic views of the arrangements of metal particles in the field effect type transistor according to a second embodiment of the present invention as viewed from a gate electrode side;

FIG. 10 shows a field effect type transistor according to a third embodiment of the present invention, in which FIG. 10A is a cross-sectional view and FIG. 10B is an enlarged cross-sectional view near a gate electrode;

FIG. 11 is a series of cross-sectional views illustrating a manufacturing process of the field effect type transistor according to the third embodiment of the present invention;

FIG. 12 is a series of cross-sectional views illustrating the manufacturing process of the field effect type transistor according to the third embodiment of the present invention;

FIG. 13 shows a field effect type transistor according to a fourth embodiment of the present invention, in which FIG. 13A is a cross-sectional view and FIG. 13B is an expanded cross-sectional view near a gate electrode;

FIG. 14 is a series of schematic views of the arrangements of metal particles in the field effect type transistor according to the third and fourth embodiments of the present invention as viewed from the gate electrode side;

FIG. 15 is a cross-sectional view of a field effect type transistor according to a fifth embodiment of the present invention;

FIG. 16 is a graph showing the relation between the equivalent thickness of a gate insulating film and the thickness of a polysilicon film which intervenes between a metal portion (metal particles) and the gate insulating film; and

FIG. 17 is a cross-sectional view of a field effect type transistor having a conventional structure.

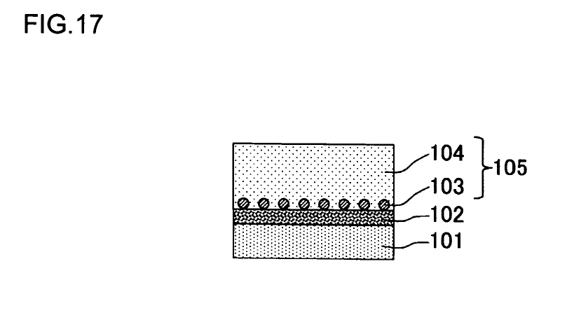

### DETAILED DESCRIPTION OF THE INVENTION

The invention will now be described by reference to the preferred embodiments. This does not intend to limit the scope of the present invention, but to exemplify the invention.

Hereinafter, the preferred embodiments embodying the invention will be described with reference to the drawings. Similar components are designated by similar numerals in all the drawings, and the description thereof will be omitted.

### First Embodiment

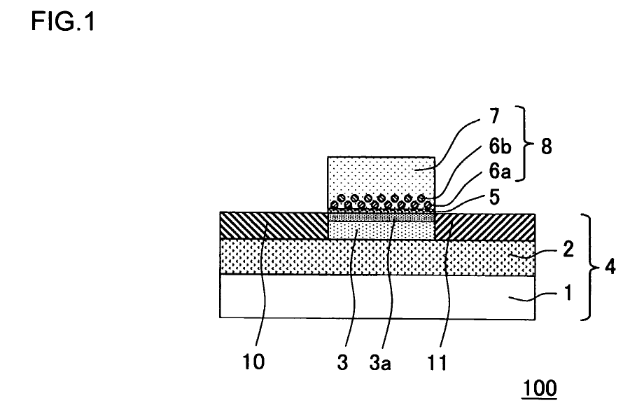

FIG. 1 is a cross-sectional view illustrating a field effect type transistor according to a first embodiment of the present invention.

A field effect type transistor 100 has an SOI (Silicon on Insulator) substrate 4 which is composed of a p-type silicon substrate 1, a buried oxide film 2, and a single crystal silicon layer 3. A source region 10 and a drain region 11 are provided in the single crystal silicon layer 3. Furthermore, in the single crystal silicon layer 3, the surface between the source region 10 and the drain region 11 serves as a channel layer 3a. A gate insulating film 5 is formed on the single crystal silicon layer 3 (the channel layer 3a). On the gate insulating film 5, a polysilicon gate electrode 8 is provided which is composed of metal particles 6a and 6b of titanium nitride (TiN) and a polycrystalline silicon film (polysilicon film) 7. Here, the metal particles of TiN are composed of a metal portion 6a being in contact with the gate insulating film 5 and a metal portion 6b being out of contact with the gate insulating film 5. The gate insulating film 5 is an example of the “insulating layer” of the present invention, and the metal particles 6a and 6b of TiN are examples of the “first metal particles” and the “second metal particles” of the present invention. Furthermore, the polycrystalline silicon film 7 is an example of the “semiconductor layer” of the present invention.

FIGS. 1 to 7 are cross-sectional views for describing a manufacturing process of the field effect type transistor according to the first embodiment of the present invention.

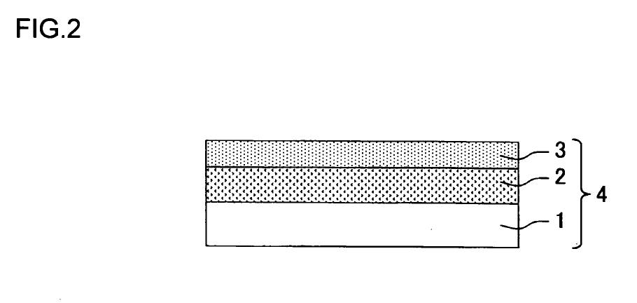

(Step 1, see FIG. 2) The SOI (Silicon on Insulator) substrate 4 is prepared which is composed of the p-type silicon substrate 1, the buried oxide film 2, and the single crystal silicon layer 3. In this instance, the thickness of the single crystal silicon layer 3 is 10 to 200 nm, and the thickness of the buried oxide film 2 is 50 to 200 nm.

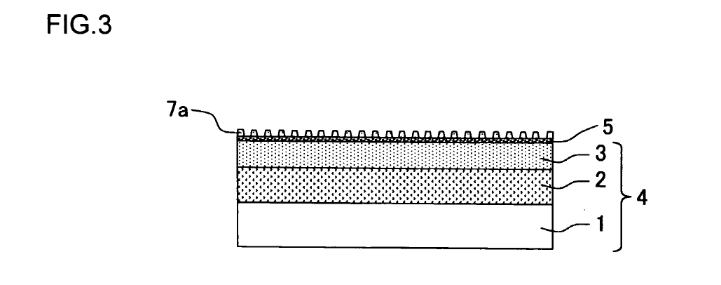

(Step 2, see FIG. 3) A silicon oxide film 5 serving as the gate insulating film 5 is formed on the Soi substrate 4 by means of a thermal oxidation method or a CVD (Chemical Vapor Deposition) method. The thickness of the silicon oxide film 5 is about 3 nm. Subsequently, a polysilicon film 7a is formed into a pattern of dots or islands on the silicon oxide film 5 in an atmosphere containing one of monosilane gas and disilane gas by means of a reduced pressure CVD method. The thickness of the polysilicon film 7a is about 3 nm.

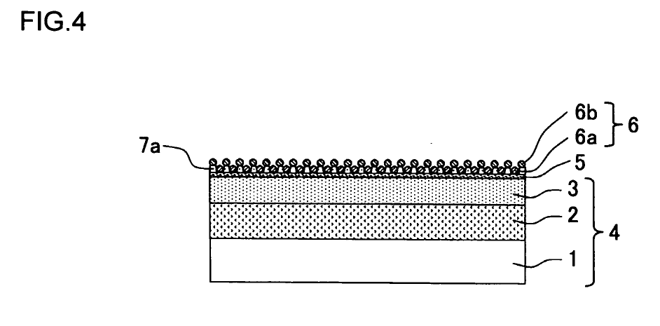

(Step 3, see FIG. 4) Subsequently, metal particles 6 of titanium nitride (TiN) are formed by means of a CVD method. Here, the metal particles formed on the silicon oxide film 5 are the metal portion 6a being in contact with the silicon oxide film 5, and the metal particles formed on the polysilicon film 7a are the metal portion 6b being out of contact with the silicon oxide film 5. In the metal particles 6, the average particle diameter of the TiN particles is about 2.5 nm for both the metal portions 6a and 6b. Here, the metal particles 6 of TiN are formed on an irregular portion composed of the silicon oxide film 5 and the dot-like polysilicon film 7a. Therefore, the metal particles 6 can be provided at higher density as compared to the case where the metal particles 6 are formed on a planar film.

Although a CVD method is employed for forming the metal particles 6, a sputtering method or other method can be employed.

Furthermore, TiN is employed as the metal particles 6, but the metal particles are not limited thereto. A material therefore may be appropriately selected, and examples thereof include at least one of metals such as W, Si, Ta, Ti, Hf, Al, Pt, Zr, Mo, V, Nb, Cr, Mn, Tc, Re, Fe, Co, and Ni, nitrogen compounds thereof, and silicon compounds thereof.

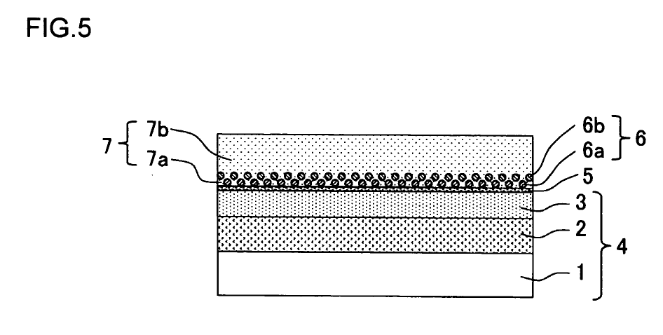

(Step 4, see FIG. 5) Subsequently, a polysilicon film 7b is formed to a thickness of about 200 nm in an atmosphere containing one of monosilane gas and disilane gas by means of a reduced pressure CVD method. In this manner, the polysilicon film 7 is formed, containing therein the metal particles 6 (6a and 6b) of TiN.

The polysilicon film 7 containing the metal particles of TiN may be formed by the following method. That is, a silicon film 7a in an amorphous state is first formed into a pattern of islands on the silicon oxide film 5. Subsequently, a thin TiN film is formed to a thickness of about 2.5 nm so as to coat the silicon oxide film 5 and the island-like silicon film 7a in an amorphous state. Furthermore, a silicon film 7b in an amorphous state is formed on the thin TiN film. Subsequently, heat treatment is performed, whereby the silicon films in an amorphous state are polycrystallized and converted to the polysilicon film 7. In this case, since the thickness of the thin TiN film is small, the thin TiN film aggregates into a particle-like (dot-like) shape, and thus the metal particles of TiN are formed.

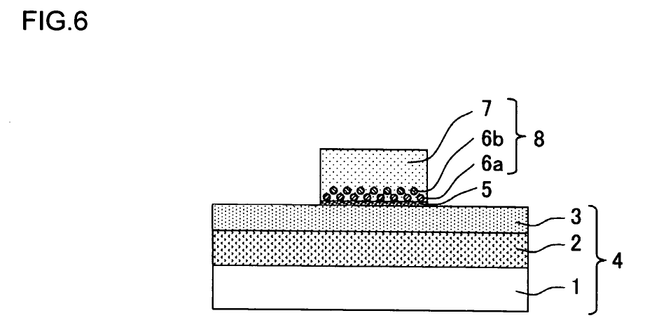

(Step 5, see FIG. 6) Unnecessary portions are removed from the polysilicon film 7, the metal particles 6a and 6b, and the silicon oxide film 5 by means of an ordinary photolithography technique and an ordinary etching technique. In this manner, the polysilicon gate electrode 8 is formed and processed into a desirable pattern.

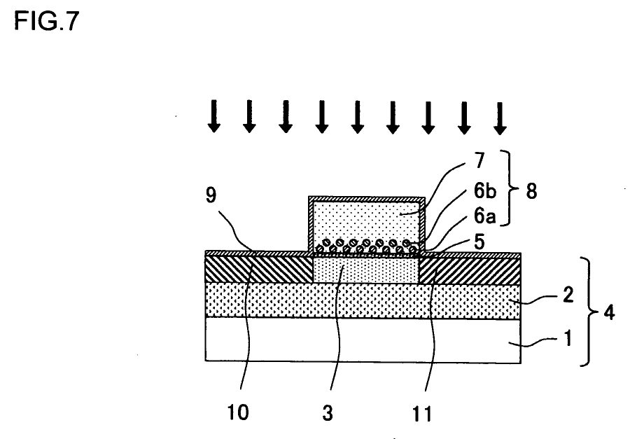

(Step 6, see FIG. 7) A protection film 9 of a silicon oxide film is formed by means of a CVD method, and subsequently an impurity for forming a source and drain is introduced into the region for the source and drain by means of an ion implantation method. In this manner, the source region 10 and the drain region 11 are formed. The ion implantation conditions are set such that, for example, phosphorus (P) is implanted at an acceleration energy of 30 keV in an injection amount of approximately 4×10¹⁵ cm⁻². In this case, phosphorus (P) is also introduced as an impurity into the polysilicon film 7.

(Step 7, see FIG. 1) Subsequently, the source region 10 and the drain region 11 are activated through heat treatment (1,000° C., 10 seconds, N₂ atmosphere). Before this step, the protection film 9 may be removed by use of hydrofluoric acid or the like.

By means of the above steps, the field effect type transistor 100 according to the first embodiment of the present invention is manufactured as shown in FIG. 1.

In the first embodiment, as described above, the metal particles 6b (the metal particles being out of contact with the gate insulating film 5) composed of particulate TiN are provided in the proximity of the interface between the gate insulating film 5 and the polysilicon gate electrode 8 (the polysilicon film 7). In this manner, carriers are supplied from the metal particles 6b, whereby the effect of suppressing depletion in the polysilicon film 7 can be achieved in a region alongside the side surface of the metal particles 6b and in a region below the metal particles 6b. Furthermore, since the metal particles 6b are not in contact with the gate insulating film 5, no effective work function shift is caused by the metal particles 6b, and no effective work function shift (shift in the threshold voltage) occurs in the polysilicon film 7 around the metal particles 6b. Therefore, in this configuration, the effect of suppressing depletion in the polysilicon film 7 can be enhanced by the metal particles 6b being out of contact with the gate insulating film 5 without causing a work function shift (threshold voltage shift). Thus, the semiconductor device 100 with high performance can be provided.

Furthermore, the polysilicon gate electrode 8 (the polysilicon film 7) contains the metal particles 6a and 6b. The metal particles 6a are in contact with the gate insulating film 5, and the metal particles 6b are disposed through a portion of the polysilicon film 7 which lies between the adjacent metal particles 6a. In this manner, in the portion of the polysilicon film 7 which lies between the adjacent metal particles 6a, carriers are supplied from the side surface of the metal particles 6a and from the lower portion of the metal particles 6b. Therefore, depletion in the proximity of the interface between the gate insulating film 5 and the polysilicon gate electrode 8 (the polysilicon film 7) can be suppressed by the carriers supplied from both the metal particles 6a and 6b. Thus, the semiconductor device 100 can be provided in which depletion is further suppressed in the polysilicon gate electrode 8.

Moreover, according to the manufacturing method of the first embodiment, the polysilicon gate electrode 8 can be formed which is composed of the polysilicon film 7 (the polysilicon films 7a and 7b) containing the metal particles 6b. Here, the metal particles 6b are disposed such that the polysilicon film 7a intervenes between the metal particles 6b and the gate insulating film 5. Therefore, the semiconductor device 100 can be manufactured in which depletion in the proximity of the interface between the polysilicon film 7a and the gate insulating film 5 can be suppressed through the supply of carriers from the metal particles 6b. In this case, no work function shift (threshold voltage shift) of the gate electrode occurs due to the influence of the metal/gate insulating film interface. Furthermore, by controlling the formation ratio of the dot-like polysilicon film 7a formed in step 2, the final ratio of the metal particles 6a to the metal particles 6b in the polysilicon gate electrode 8 can be adjusted. Therefore, adjustment of the work function (control of the threshold voltage) of the polysilicon gate electrode can be achieved more effectively than where a conventional metal gate electrode being in contact with the gate insulating film 5. Moreover, since the metal particles including the metal particles 6a and 6b can be formed in a single process, the manufacturing cost of the semiconductor device 100 can be reduced.

Therefore, the semiconductor device 100 can be provided in which adjustment of the work function (control of the threshold voltage) of the polysilicon gate electrode 8 can be achieved while depletion in the polysilicon film 7 provided on the gate insulating film 5 is suppressed. Furthermore, a method for manufacturing the above semiconductor device 100 can be provided.

Furthermore, in the first embodiment, an impurity can easily be introduced, through step 6 or the diffusion of the impurity during heat treatment thereafter, into the proximity of a portion of the polysilicon film 7 which is in contact with the gate insulating film 5. Therefore, the impurity not only provides the effect of suppressing depletion but also allows the work function of the polysilicon gate electrode 8 to be adjusted. In particular, an impurity can easily be introduced into a portion of the polysilicon film 7 which is located below the metal particles 6b (a portion formed initially as the silicon film 7a in an amorphous state). Therefore, depletion in the polysilicon film 7 can be suppressed more effectively.

### Second Embodiment

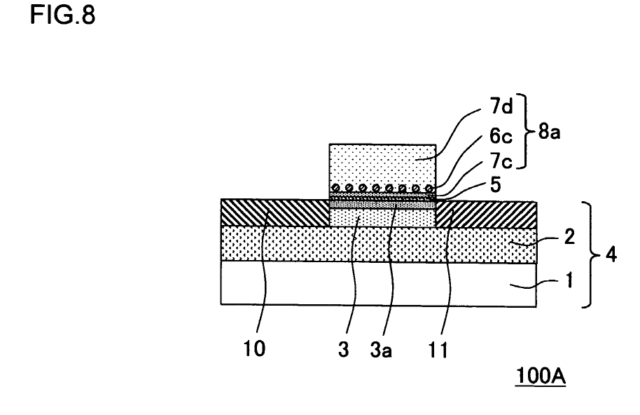

FIG. 8 is a cross-sectional view illustrating a field effect type transistor according to a second embodiment of the present invention. The difference between the present embodiment and the first embodiment is that a polysilicon gate electrode 8 (8a) is formed as a stacked body composed of a polysilicon film 7c, metal particles 6c, and a polysilicon film 7d. The polysilicon film 7c is provided on the gate insulating film 5, and the metal particles 6c made of particulate titanium nitride (TiN) are provided on the polysilicon film 7c. In the second embodiment, metal particles being in contact with the gate insulating film 5 are not included. The rest of the configuration is the same as that in the first embodiment.

The manufacturing process is the same as that of the first embodiment, except that a method for forming the metal particles and the polysilicon film is different in steps 2 to 4. A specific method for forming the metal particles 6c and the polysilicon films 7c and 7d is as follows.

The polysilicon film 7c is uniformly formed to a thickness of about 3 nm on the silicon oxide film 5 in an atmosphere containing one of monosilane gas and disilane gas by means of a reduced pressure CVD method. Subsequently, the metal particles 6c of TiN (the average particle size of the TiN particles is about 3 nm) are formed by means of a CVD method. Then, the polysilicon film 7d is formed to a thickness of about 150 nm in an atmosphere containing one of monosilane gas and disilane gas by means of a reduced pressure CVD method. In this manner, the stacked body serving as the polysilicon gate electrode 8a in subsequent steps is formed. In this instance, the polysilicon film 7c and the polysilicon film 7d may have the same composition. Furthermore, the composition of the polysilicon film 7c may be different from the composition of the polysilicon film 7d in accordance with the required performance. The metal particles 6c of TiN are an example of the “metal portion” of the present invention.

In a field effect type transistor 100A of the second embodiment, depletion in the proximity of the interface between the gate insulating film 5 and the polysilicon film 7c constituting the polysilicon gate electrode 8a can be suppressed through the supply of carriers from the metal particles 6c. Furthermore, the polysilicon film 7c intervenes between the metal particles 6c of TiN and the gate insulating film 5. Therefore, since the metal particles 6c are out of contact with the gate insulating film 5, the effective work function of the metal particles 6c of TiN is not affected by the insulating film. In particular, when a gate insulating film such as a silicon oxide (SiO₂) film or a silicon oxynitride (SiON) film is employed, no work function shift (threshold voltage shift) of the polysilicon gate electrode 8a occurs. Therefore, adjustment of the work function (control of the threshold voltage) of the polysilicon gate electrode 8a can easily be achieved.

Therefore, also in the second embodiment, a semiconductor device can be provided in which adjustment of the work function (control of the threshold voltage) of the polysilicon gate electrode 8a can be achieved while depletion in the polysilicon film provided on the gate insulating film 5 is suppressed. Furthermore, a method for manufacturing the above semiconductor device can be provided.

Moreover, in the second embodiment, the metal particles 6c are formed on the polysilicon film 7c and thus are disposed uniformly and two-dimensionally. Therefore, the effect of suppressing depletion in the polysilicon film is homogenized, and adjustment of the work function (control of the threshold voltage) of the polysilicon gate electrode 8a can easily be achieved. Thus, a semiconductor device with less performance variation can be provided.

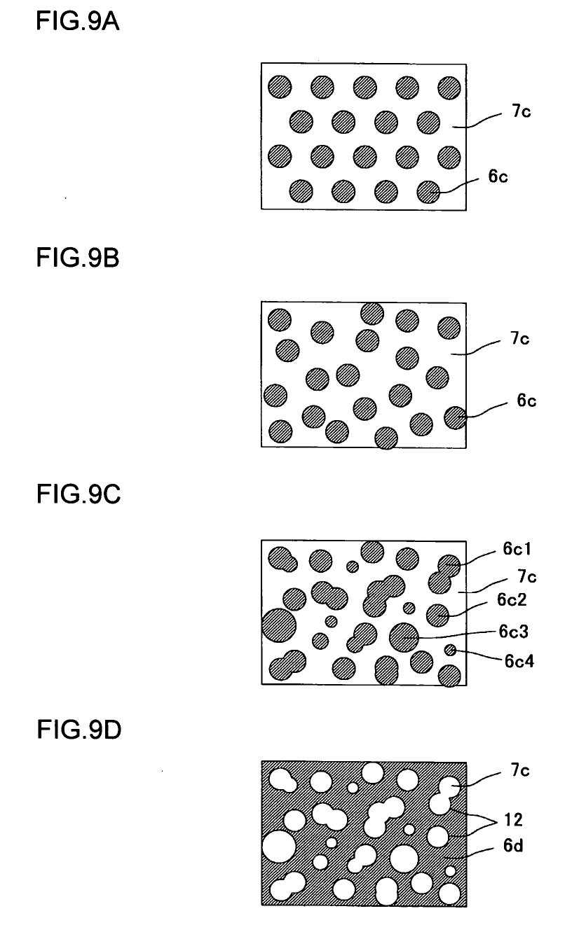

FIG. 9 is a series of schematic views of arrangements of the metal portion in the field effect type transistor of the present invention as viewed from the gate electrode side (the upper side). In the second embodiment, the metal particles 6c are regularly arranged on the polysilicon film 7c as shown in the arrangement diagram (FIG. 9A). However, more realistically, the metal particles are not uniformly arranged, and the density thereof is also non-uniform. For example, the metal particles may be randomly arranged as shown in the arrangement diagram (FIG. 9B). Furthermore, the metal particles may include a coalesced metal particle 6c1 formed by particles connecting to each other, and metal particles 6c2, 6c3, and 6c4 of various sizes, and these particles may be randomly arranged as shown in the arrangement diagram (FIG. 9C). The shape of the metal particles is not necessarily spherical, but the metal particles may have a shape such as an ellipsoidal shape, a rod-like shape, or a polyhedral shape. Furthermore, an arrangement shown in the arrangement diagram (FIG. 9D) may be employed, in which the metal particles are coalesced with each other to form a thin metal film 6d, with apertures 12 (openings at which the polysilicon film 7c is exposed) formed in the thin metal film 6d.

### Third Embodiment

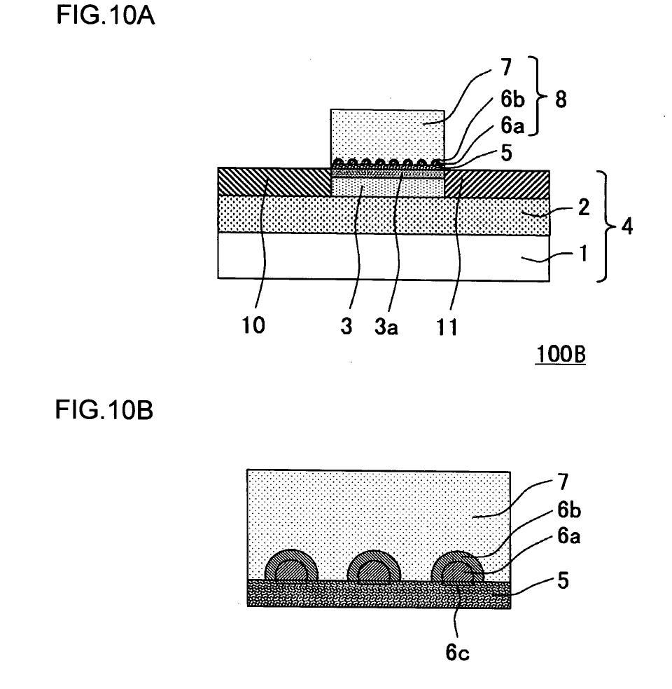

FIG. 10A is a cross-sectional view illustrating a field effect type transistor according to a third embodiment of the present invention. FIG. 10B is an enlarged cross-sectional view illustrating the proximity of a gate electrode of the transistor shown in FIG. 10A.

A field effect type transistor 100B has an SOI (Silicon on Insulator) substrate 4 which is composed of a p-type silicon substrate 1, a buried oxide film 2, and a single crystal silicon layer 3. Furthermore, a source region 10 and a drain region 11 are provided in the single crystal silicon layer 3. In the single crystal silicon layer 3, the surface between the source region 10 and the drain region 11 serves as a channel layer 3a. A gate insulating film 5 is formed on the single crystal silicon layer 3 (the channel layer 3a). A polycrystalline silicon gate electrode 8 composed of metal particles 6a of titanium nitride (TiN) and polycrystalline silicon film (polysilicon film) 7 is provided on the gate insulating film 5. A silicide reaction occurs between titanium (Ti) atoms in the metal particles 6a and silicon (Si) atoms in the polycrystalline silicon film 7 to form a titanium silicide (TiSiₓ) reaction layer 6b between the metal particles 6a of TiN and the polycrystalline silicon film 7. Furthermore, the metal particles 6a of TiN are arranged so as to contact the gate insulating film 5. Thus, titanium (Ti) atoms in the metal particles 6a react with silicon (Si) and oxygen (O) atoms in the gate insulating film 5 to form a reaction layer 6c between the metal particles 6a and the gate insulating film 5. Here, the gate insulating film 5 is an example of the “insulating layer” of the present invention, and the metal particles 6a of TiN are an example of the “metal particles” of the present invention. The titanium silicide reaction layer 6b is an example of the “first reaction layer” of the present invention, and the reaction layer 6c is an example of the “second reaction layer” of the present invention. The polycrystalline silicon film 7 is an example of the “semiconductor layer” of the present invention.

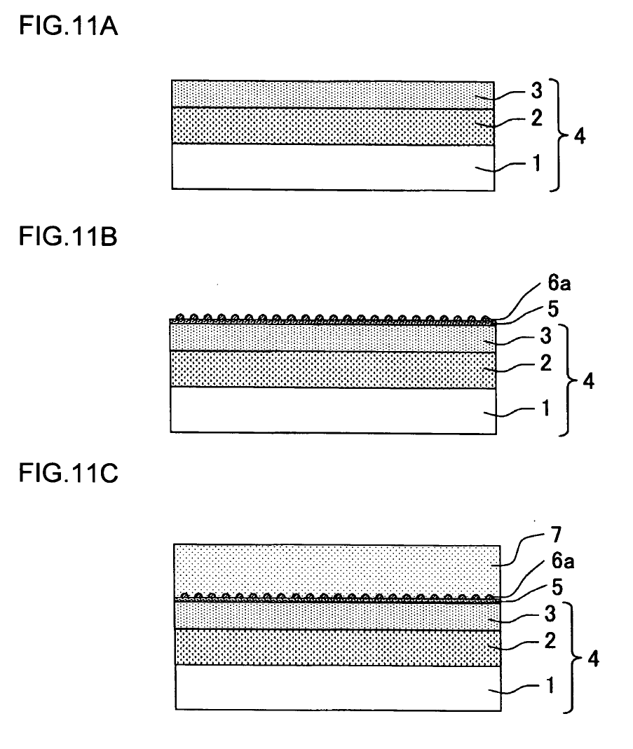

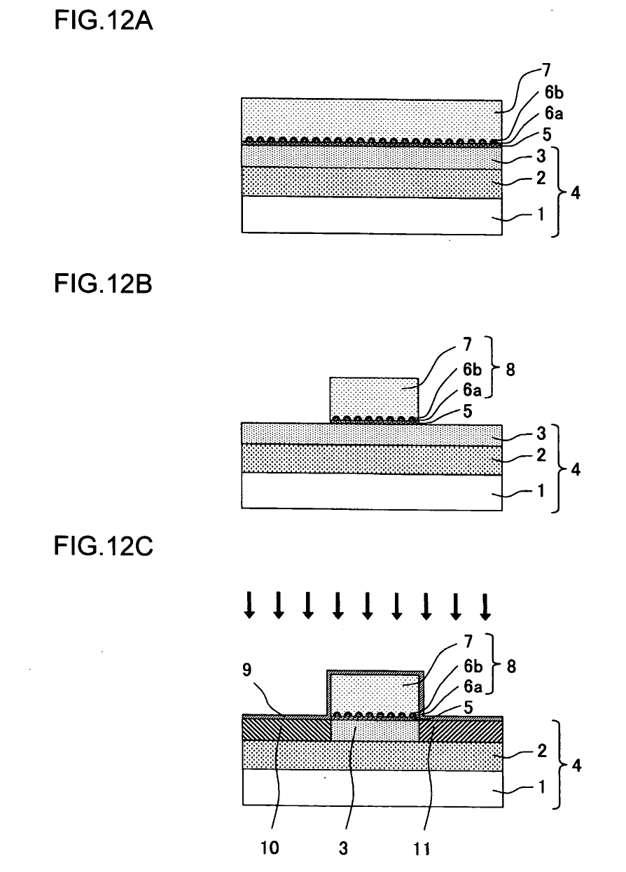

Each of FIGS. 11 and 12 is a series of cross-sectional views for describing a manufacturing process of the field effect type transistor according to the third embodiment of the present invention.

(Step 1, see FIG. 11A) The SOI (Silicon on Insulator) substrate 4 is prepared, which is composed of the p-type silicon substrate 1, the buried oxide film 2, and the single crystal silicon layer 3. Here, the thickness of the single crystal silicon layer 3 is 10 to 200 nm, and the thickness of the buried oxide film 2 is 50 to 200 nm.

(Step 2, see FIG. 11B) A silicon oxide film 5 serving as the gate insulating film is formed on the SOI substrate 4 by means of a thermal oxidation method or a CVD (Chemical Vapor Deposition) method. The thickness of the silicon oxide film 5 is about 3 nm. Subsequently, the metal particles 6a of titanium nitride (TiN) are formed by means of a sputtering method. In order to promote the formation of the metal particles, heat treatment at 600° C. to 700° C. may be performed after the titanium nitride is stacked. In this instance, the metal particles 6a are formed on the silicon oxide film 5 so as to be in contact with this film 5. The average particle size of the metal particles 6a of TiN is about 3 nm. Furthermore, the metal particles 6a are formed such that the ratio of metal atoms (Ti atoms) therein is higher than the ratio of nitrogen atoms (N atoms) therein. For example, a reactive sputtering method may be employed as the formation method of the metal particles 6a. In this case, a titanium target is sputtered by use of a gas mixture of nitrogen gas and argon gas. By adjusting the partial pressure of the nitrogen gas in the gas mixture atmosphere to about 15%, metal particles made of TiN and having a higher titanium content may be formed. During heat treatment described later, a silicide reaction occurs between the polycrystalline silicon film 7 and Ti atoms on the surface of the metal particles 6a of TiN. Due to the excessive quantity of Ti atoms on the metal particles 6a, the silicide reaction is further facilitated, whereby the titanium silicide (metal silicide) 6b can be formed. Moreover, the excessive Ti atoms in the metal particles 6a react with silicon and oxygen atoms contained in the gate insulating film 5, whereby the reaction layer 6c can be formed. However, when the ratio of Ti atoms in the metal particles 6a of TiN is equal to or less than the ratio of N atoms therein, the metal silicide (titanium silicide) 6b and the reaction layer 6c cannot be formed on the surface of the metal particles 6a. This is because the reactivity is low at a heat treatment temperature in step 4 described later.

Although a sputtering method is employed for forming the metal particles 6, the metal particles 6 may be formed by means of a CVD method or other method.

Furthermore, TiN is employed as the metal particles 6, but the metal particles are not limited thereto. For example, a material can be appropriately selected and employed which contains at least one of metals such as W, Si, Ta, Ti, Hf, Al, Pt, Zr, Mo, V, Nb, Cr, Mn, Tc, Re, Fe, Co, and Ni, nitrogen compounds thereof, and silicon compounds thereof.

(Step 3, see FIG. 1C) Subsequently, the polycrystalline silicon film 7 is formed to a thickness of about 200 nm at a temperature of, for example, 630° C. in an atmosphere containing one of monosilane gas and disilane gas by means of a reduced pressure CVD method. In this manner, the polycrystalline silicon film 7 is formed, containing therein the metal particles 6a of TiN.

(Step 4, see FIG. 12A) Subsequently, heat treatment is performed at temperatures of 600° C. to 700° C. (more preferably a temperature of 630° C.). During the heat treatment, a silicide reaction occurs between Ti atoms in the metal particles 6a and silicon (Si) atoms in the polycrystalline silicon film 7 to form the titanium silicide (TiSiₓ) reaction layer 6b between the metal particles 6a of TiN and the polycrystalline silicon film 7. At this time, as shown in FIG. 10B, a reaction also occurs between Ti atoms in the metal particles 6a and Si and O atoms in the gate insulating film 5 to form the reaction layer 6c between the gate insulating film 5 and the metal particles 6a, which are arranged so as to be in contact with the gate insulating film 5.

When the ratio of Ti atoms in the metal particles 6a of TiN is the same as the ratio of N atoms therein, the heat treatment temperature must be 1,000° C. or higher in order for the silicide reaction to take place. For example, a heat treatment process with particular conditions (an RTA (Rapid Thermal Annealing) method: 1050° C., one second, N₂ atmosphere) may be employed. However, when the ratio of Ti atoms is higher than the ratio of N atoms, the silicide reaction occurs in the temperature range of 400° C. to 650° C. or higher (630° C. in the present invention). Therefore, the heat treatment temperature for forming the reaction layer can be reduced. Since the reaction layer can be formed without affecting the impurity profile of a transistor, a semiconductor device having improved reliability can be stably manufactured with high reproducibility.

Furthermore, the reaction layer can also be formed at low temperatures by use of a metal itself or a metal silicide having a higher ratio of the metal, in place of the TiN metal particles (Ti rich particles). When a metal itself is employed, the silicide reaction temperature is 400° C. to 650° C. or higher. When a metal silicide is employed, the silicide reaction temperature is 400° C. to 650° C. or higher. Thus, these materials may be selected and employed as appropriate.

The titanium silicide reaction layers 6b and 6c on the surface of the metal particles 6a, and the polycrystalline silicon film 7 containing therein the metal particles 6a of TiN, may be formed by the following method. A thin TiN film is formed to a thickness of about 3 nm so as to coat the gate insulating film 5, and an amorphous silicon film 7b is formed on the thin TiN film. Subsequently, heat treatment is performed, whereby the amorphous silicon film 7b is polycrystallized and converted to the polysilicon film 7. During the heat treatment, since the thickness of the thin TiN film is small, the thin TiN film aggregates into particle-like (dot-like) shapes, and thus the metal particles 6a of TiN are formed. At the same time, the titanium silicide reaction layer 6b is formed between the thus-formed metal particles 6a and the polycrystalline silicon film 7, and the reaction layer 6c is formed between the metal particles 6a and the gate insulating film 5.

(Step 5, see FIG. 12B) Unnecessary portions are removed from the polycrystalline silicon film 7, the metal particles 6a, the titanium silicide reaction layer 6b, the reaction layer 6c, and the silicon oxide film 5 by means of an ordinary photolithography technique and an ordinary etching technique. In this manner, the polycrystalline silicon gate electrode 8 is formed and processed into a desirable pattern.

(Step 6, see FIG. 12C) A protection film 9 of a silicon oxide is formed by means of a CVD method, and subsequently an impurity for forming a source and drain is introduced into the appropriate region for the source and drain by means of an ion implantation method. In this manner, the source region 10 and the drain region 11 are formed. The ion implantation conditions are set such that, for example, phosphorus (P) is implanted at an acceleration energy of 30 keV in an injection amount of about 4×10¹⁵ cm⁻². In this case, phosphorus (P) is also implanted as an impurity into the polycrystalline silicon film 7.

(Step 7, see FIG. 10) Subsequently, the source region 10 and the drain region 11 are activated through heat treatment (1,000° C., 10 seconds, N₂ atmosphere) by means of an RTA method. Before this step, the protection film 9 may be removed by use of hydrofluoric acid or the like.

Through the above steps, the field effect type transistor 100B according to the third embodiment of the present invention is manufactured as shown in FIG. 10.

In the third embodiment, the metal particles 6a of particulate TiN are provided in the proximity of the interface between the gate insulating film 5 and the polycrystalline silicon gate electrode 8 (the polycrystalline silicon film 7) as described above. Hence, depletion in the proximity of the interface between the polycrystalline silicon film 7 and the gate insulating film 5 can be suppressed by supplying carriers (charges) from the metal particles 6a through the silicide reaction layer 6b. In addition, the contact area between the metal particles 6a and the gate insulating film 5 can be reduced as compared with a conventional metal gate electrode. Accordingly, the effective work function shift, which occurs in the proximity of the metal particle/insulating layer interface, is less likely to occur. Therefore, adjustment of the work function (control of the threshold voltage) of the polycrystalline silicon gate electrode 8 (the polycrystalline silicon film 7) can more easily be achieved as compared with a conventional metal gate electrode.

Furthermore, since the metal particles 6a are physically bonded to the polycrystalline silicon film 7 through chemical bonding with the titanium silicide reaction layer 6b, the bonding strength between the metal particles 6a and the polycrystalline silicon film 7 is enhanced. Thus, the adhesive properties between the metal particles 6a and the polycrystalline silicon film 7 are improved, and the reliability of the semiconductor device 100B is improved. Furthermore, since the metal particles 6a are physically bonded to the gate insulating film 5 through chemical bonding with the reaction layer 6c, the bonding strength between the metal particles 6a and the gate insulating film 5 is also enhanced in the proximity of the interface between the metal particles 6a and the gate insulating film 5. Thus, the adhesive properties between the metal particles 6a and the gate insulating film 5 are improved, and the reliability of the semiconductor device 100B is further improved.

Moreover, the metal particles 6a are electrically in contact with the polycrystalline silicon film 7 through the titanium silicide reaction layer 6b, which is a metal silicide formed through the reaction of Ti atoms contained in the metal particles 6a with Si atoms contained in the polycrystalline silicon film 7. Therefore, the electrical resistance between the polycrystalline silicon film 7 and the metal particles 6a is reduced. In this manner, the supply of carriers from the metal particles 6a to the polycrystalline silicon film 7 is facilitated, and thus the effect of suppressing depletion in the polycrystalline silicon film 7, which effect is obtained by providing the metal particles 6a in the proximity of the gate insulating film 5, can be enhanced.

According to the manufacturing method of the third embodiment, the titanium silicide reaction layer 6b can easily be provided through the reaction which occurs between the metal particles 6a and the polycrystalline silicon film 7 during the heat treatment. Therefore, additional facility investment is not required, and a semiconductor device having improved reliability can be manufactured at low cost.

As described above, the semiconductor device 100B is provided in which adjustment of the work function (control of the threshold voltage) of the polycrystalline silicon gate electrode 8 can be achieved while depletion in the polycrystalline silicon film 7 provided on the gate insulating film 5 is suppressed. According to the third embodiment, the adhesive properties between the metal particles 6a and the films around them are also improved, and therefore the semiconductor device 100B having excellent reliability can be provided. Furthermore, a method for manufacturing the above semiconductor device 100B can be provided.

In addition, in the third embodiment, the impurity can be easily introduced, through step 5 or the diffusion of the impurity during heat treatment thereafter, into the proximity of a portion of the polycrystalline silicon film 7 which is in contact with the gate insulating film 5. Thus, the impurity not only provides the effect of suppressing depletion but also allows the work function of the polycrystalline silicon gate electrode 8 to be adjusted.

### Fourth Embodiment

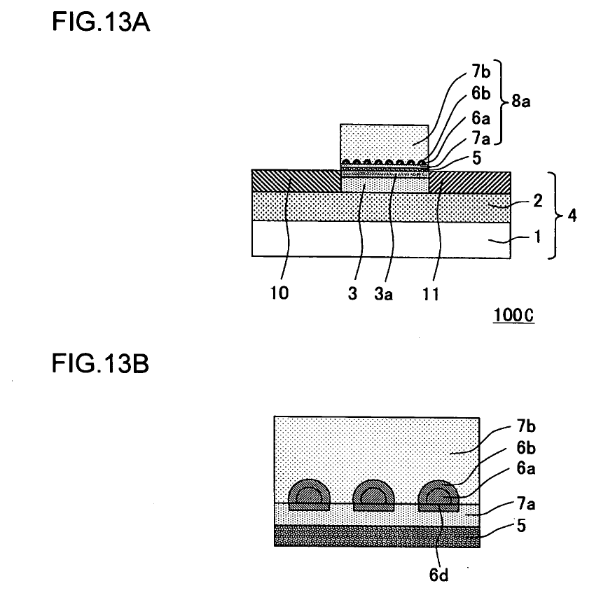

FIG. 13A is a cross-sectional view illustrating a field effect type transistor according to a fourth embodiment of the present invention. FIG. 13B is an enlarged cross-sectional view near a gate electrode of the transistor shown in FIG. 13A. The differences between the present embodiment and the third embodiment are: (1) a polycrystalline silicon gate electrode 8 (8a) is composed of a polycrystalline silicon film 7a provided on the gate insulating film 5, the metal particles 6a made of particulate TiN and provided on the polycrystalline silicon film 7a, and a polycrystalline silicon film 7b; and (2) a titanium silicide reaction layer 6d is formed between the metal particles 6a and the polycrystalline silicon film 7a through a silicide reaction between Ti atoms in the metal particles 6a and Si atoms in the polycrystalline silicon film 7a. The rest of the configuration is the same as that in the third embodiment.

The manufacturing process is the same as that of the third embodiment, except that a method for forming the metal particles and the polysilicon film is different in steps 2 to 4. Specifically, a method for forming the metal particles 6a and the polysilicon films 7a and 7b is as follows.

The polycrystalline silicon film 7a is uniformly formed to a thickness of about 3 nm on the silicon oxide film 5 in an atmosphere containing one of monosilane gas and disilane gas by means of a reduced pressure CVD method. Subsequently, the metal particles 6a of TiN (the average particle size of TiN is about 3 nm) are formed by means of a sputtering method. Then, the polycrystalline silicon film 7b is formed to a thickness of about 150 nm in an atmosphere containing one of monosilane gas and disilane gas by means of a reduced pressure CVD method. In this manner, a stacked body serving as the polysilicon gate electrode 8a in subsequent steps is formed.

In a field effect type transistor 100C of the fourth embodiment, the polycrystalline silicon film 7a intervenes between the metal particles 6a of TiN and the gate insulating film 5. Therefore, since the metal particles 6a are not in direct contact with the gate insulating film 5, the effective work function of the metal particles 6a of TiN is not affected by the insulating film. In particular, when a gate insulating film such as a silicon oxide (SiO₂) film or a silicon oxynitride (SiON) film is employed, no effective work function shift (threshold voltage shift) of the polycrystalline silicon gate electrode 8a occurs. Therefore, adjustment of the effective work function (control of the threshold voltage) of the polycrystalline silicon gate electrode 8a can easily be achieved. Furthermore, the effect of suppressing depletion in the polycrystalline silicon film 7a can be achieved in a portion below the metal particles 6a. Thus, the threshold voltage shift of the gate electrode can be suppressed as compared to the conventional case in which metal particles are in contact with a gate insulating film.

Furthermore, since the bonding strength between the metal particles 6a and the polycrystalline silicon films 7a and 7b around them is enhanced due to the intervention of the titanium silicide reaction layers 6b and 6d, the adhesive properties between the metal particles 6a and the polycrystalline silicon films 7a and 7b are improved. Thus, the reliability of the semiconductor device 100C is improved.

Moreover, since the metal particles 6a are electrically in contact with the polycrystalline silicon films 7a and 7b through the titanium silicide reaction layers 6b and 6d, which are a metal silicide, the electrical resistance between the polycrystalline silicon films 7a and 7b and the metal particles 6a is reduced. In this manner, the supply of carriers from the metal particles 6a to the polycrystalline silicon film 7 is facilitated and thus the effect of suppressing depletion in the polycrystalline silicon film 7a, achieved by providing the metal particles 6a in the proximity of the gate insulating film 5, can be enhanced.

As described above, the semiconductor device 100C is provided in which adjustment of the effective work function (control of the threshold voltage) of the polycrystalline silicon gate electrode 8a can be achieved while depletion in the polycrystalline silicon film 7a provided on the gate insulating film 5 is suppressed. According to the fourth embodiment, the adhesive properties between the metal particles 6a and the films around them are also improved, and thus the semiconductor device 100C having excellent reliability can be provided.

Furthermore, in the fourth embodiment, the metal particles 6a are formed on the polycrystalline silicon film 7a and thus are disposed uniformly and two-dimensionally. Therefore, the effect of suppressing depletion in the polycrystalline silicon film 7a is homogenized, and adjustment of the effective work function (control of the threshold voltage) of the polycrystalline silicon gate electrode 8a can easily be achieved. Thus, a semiconductor device with less performance variation can be provided.

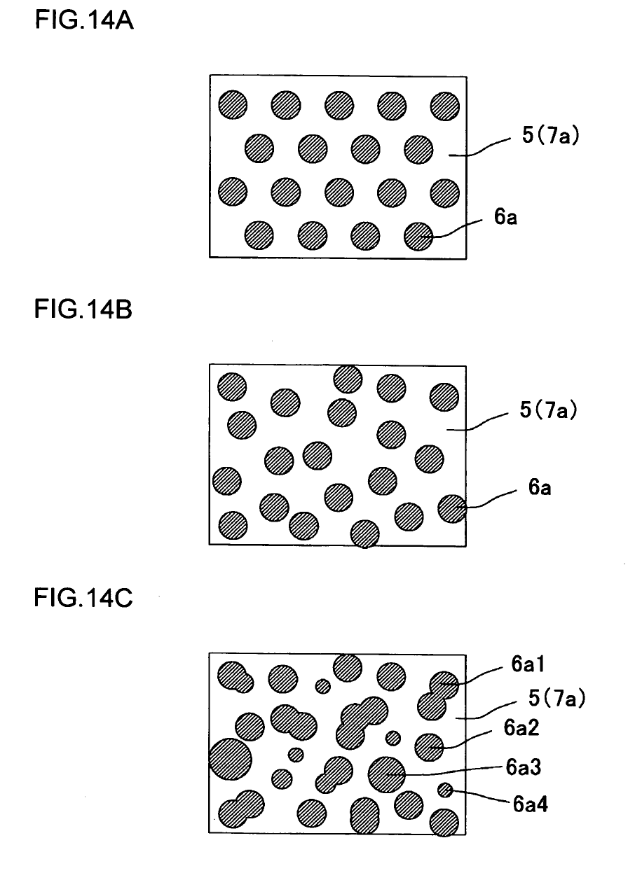

FIG. 14 is a series of schematic views of the arrangements of the metal particles 6a in the field effect type transistor of the present invention as viewed from the gate electrode side (the upper side). In the third and fourth embodiments, the metal particles 6a are regularly arranged on the gate insulating film 5 (the polycrystalline silicon film 7a) as shown in the arrangement diagram (FIG. 14A). However, more realistically, the metal particles are not uniformly arranged, and the density thereof is also non-uniform. Therefore, for example, the metal particles may be randomly arranged as shown in the arrangement diagram (FIG. 14B). Furthermore, as shown in the arrangement diagram (FIG. 14C), the metal particles may include a coalesced metal particle 6a l formed by particles connecting to each other and metal particles 6a2, 6a3, and 6a4 of various sizes, and these particles may be randomly arranged. The metal particles are not necessarily spherical, but may have a shape such as an ellipsoidal shape, a rod-like shape, or a polyhedral shape.

### Fifth Embodiment

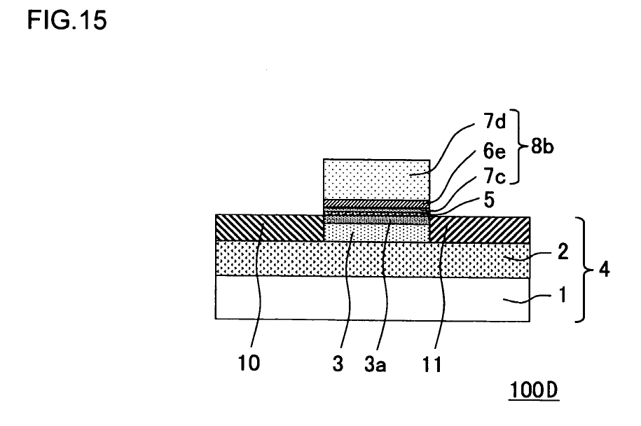

FIG. 15 is a cross-sectional view illustrating a field effect type transistor according to a fifth embodiment of the present invention. The difference from the second embodiment is that a thin metal film 6e of TiN (a thin film not having the apertures 12 in contrast to the thin metal film 6d) is employed in place of the metal particles 6c which is made of particulate titanium nitride (TiN) and is provided on the polysilicon film 7c. The rest of the configuration is the same as that in the second embodiment.

As for the manufacturing process, the method for forming the thin metal film 6e is different from the method for forming the metal particles 6c (the thin metal film 6d) in the second embodiment. The other steps are the same as those of the second embodiment. A specific method for forming the thin metal film 6e is as follows. The thin metal film 6e of TiN (the average thickness of the thin TiN film is about 3 nm) is formed by means of a CVD method. In this case, heat treatment, which causes aggregation of the thin metal film 6e, is not performed after the formation of the thin metal film 6e. In this manner, a stacked film is formed which serves as a polysilicon gate electrode 8b in subsequent steps.

In a field effect type transistor 100D of the fifth embodiment, adjustment of the work function (control of the threshold voltage) of the polysilicon gate electrode 8b can be achieved while depletion in the polysilicon film 7c provided on the gate insulating film 5 is suppressed. In addition, the metal thin film 6e is inserted into the polysilicon gate electrode 8b to form a stacked structure of the polysilicon film 7d/the thin metal film 6e/the polysilicon film 7c. Therefore, in contrast to the case of a polysilicon gate electrode composed of a single polysilicon film, non-continuity can be provided in a cylindrical structure of the polysilicon films. Therefore, when the impurity is introduced by means of ion implantation in step 6, ion channeling (implantation of the impurity into the channel layer 3a) can be suppressed, and thus the characteristics of the transistor can be stabilized. Furthermore, after the ion implantation, the impurity concentration in the polysilicon gate electrode 8b changes abruptly at the thin metal film 6e. That is, the impurity is not implanted into the polysilicon film 7c. Hence, during subsequent heat treatment for impurity diffusion, the impurity is allowed to diffuse uniformly into the polysilicon film 7c from the thin metal film 6e, and thus the impurity concentration in the polysilicon film 7c can be easily controlled. Therefore, the semiconductor device 100D having transistor characteristics with less performance variation can be provided.

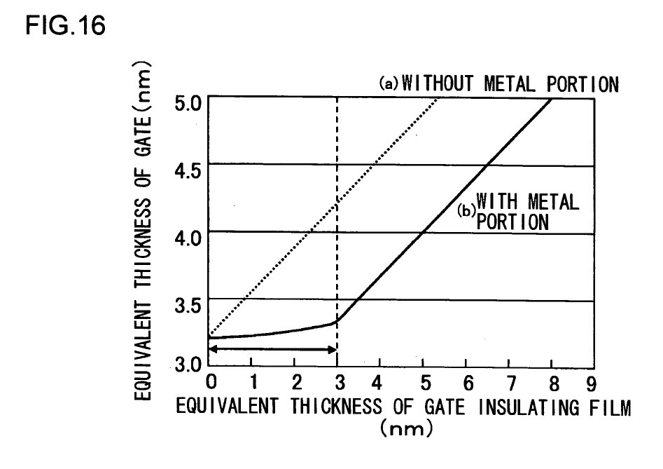

FIG. 16 is a graph showing the relation between the equivalent thickness of a gate insulating film and the thickness of a polysilicon film intervening between a metal portion (metal particles) and the gate insulating film. As is clear from FIG. 16, the equivalent thickness of the gate insulating film can be reduced when the metal portion is present. This is because, when the metal portion is not present, the apparent thickness of the gate insulating film (the equivalent thickness thereof) increases since the total capacitance is determined by the series capacitance of the gate insulating film (a silicon oxide film: er=3.9) and the depleted polysilicon film (Er=11.7). Moreover, as can be seen, when the thickness of the polysilicon film provided in the lower portion of the metal portion (intervening between the metal portion and the gate insulating film) is 3 nm or less, an abrupt increase in the equivalent thickness of the gate insulating layer can be avoided. This is because carriers are efficiently supplied from the metal portion to the bottom portion of the polysilicon film (the proximity of the gate insulating film). Hence, depletion in the proximity of the interface between the polysilicon film and the gate insulating film is reliably suppressed.

The embodiments disclosed herein are to be considered in all aspects to be illustrative but not restrictive. The present invention is defined by the scope of the claims rather than by the description of the foregoing embodiments, and all modifications within the scope of the claims and within the meaning and scope of equivalence of the claims are intended to be included within the scope of the present invention.

In the foregoing embodiments, a field effective type MOS transistor is formed by use of an SOI substrate, but the present invention is not limited thereto. For example, a field effective type MOS transistor may be formed by use of a commonly used single crystal silicon substrate such as a polished substrate or an epitaxial substrate.

Moreover, in the third and fourth embodiments, the heat treatment for forming the reaction layer (step 4) is additionally performed after step 3. However, the heat treatment performed when the polycrystalline silicon film 7 is formed in step 3 may also serve as the heat treatment in step 4. In this case, the reaction layer can be formed without adding a separate step, and thus the semiconductor device can be manufactured at low cost.

Furthermore, the heat treatment for forming the reaction layer (step 4) may be performed after the polycrystalline silicon gate electrode 8 is formed in step 5, or the heat treatment for activation processing in step 7 may also serve as the heat treatment for forming the reaction layer.

Moreover, the above embodiments 1 through 4 show examples in which a plurality of metal particles 6b is included. However, it is needless to say that, when at least one metal particle 6b is present, the effect of suppressing depletion can be achieved in a small region in the polysilicon film 7 around the metal particle 6b.

What is claimed is:

1. A semiconductor device comprising:
a semiconductor substrate having a principal surface;
a channel region provided in the principal surface of the semiconductor substrate;
an insulating layer provided on the channel region; and
a semiconductor layer provided on the insulating layer, wherein
the semiconductor layer contains a metal portion disposed in a lower region of the semiconductor layer, and
the metal portion is out of contact with the insulating layer.

2. The semiconductor device according to claim 1, wherein the metal portion comprises a plurality of first metal particles.

3. The semiconductor device according to claim 2, wherein the semiconductor layer contains a plurality of second metal particles which is disposed in the semiconductor layer, and which is in contact with the insulating layer.

4. The semiconductor device according to claim 3, wherein the spacing between the adjacent second metal particles is smaller than a size of the second metal particles, and
at least some of the first metal particles have a size the same as that of the second metal particles and are disposed via a portion of the semiconductor layer which is between the adjacent second metal particles.

5. The semiconductor device according to claim 3, wherein the first metal particles and the second metal particles are arranged two-dimensionally in a lower region of the semiconductor layer.

6. The semiconductor device according to claim 1, wherein the semiconductor layer contains an impurity of a predetermined conduction type and the impurity is introduced into the semiconductor layer by implantation.

7. The semiconductor device according to claim 2, wherein the semiconductor layer contains an impurity of a predetermined conduction type and the impurity is introduced into the semiconductor layer by implantation.

8. The semiconductor device according to claim 3, wherein at least some of the first metal particles are disposed via a portion of the semiconductor layer which is between the adjacent second metal particles.

9. The semiconductor device according to claim 3, wherein the semiconductor layer contains an impurity of a predetermined conduction type and the impurity is introduced into the semiconductor layer by implantation.

10. The semiconductor device according to claim 1, wherein the metal portion comprises a thin metal film.

11. The semiconductor device according to claim 1, wherein a thickness of the semiconductor layer between the metal portion and the insulating layer is 3 nm or less.

12. A semiconductor device comprising:
a semiconductor substrate having a principal surface;
a channel region provided in the principal surface of the semiconductor substrate;
an insulating layer provided on the channel region; and
a semiconductor layer provided on the insulating layer, wherein
the semiconductor layer contains a plurality of metal particles disposed in a lower region of the semiconductor layer, and
a first reaction layer formed through reaction with the semiconductor layer is provided on the surface of the metal particles.

13. The semiconductor device according to claim 12, wherein: some of the metal particles are arranged so as to be in contact with the insulating layer; and a second reaction layer formed through reaction with the insulating layer is provided in the proximity of an interface between the metal particles and the insulating layer.

14. The semiconductor device according to claim 12, wherein: the semiconductor layer is formed of a film containing silicon; and the first reaction layer is formed of a metal silicide.

15. The semiconductor device according to claim 14, wherein the metal particles are formed of a metal nitride and a ratio of the metal atoms forming the metal nitride is higher than a ratio of nitrogen atoms forming the metal nitride.

16. A method for manufacturing a semiconductor device, comprising:
a first step of forming an insulating layer on a channel region provided on a principal surface of a semiconductor substrate;
a second step of forming a first semiconductor layer into a pattern of dots on the insulating layer;
a third step of forming a plurality of metal particles on the insulating layer and the first semiconductor layer;
a fourth step of forming a second semiconductor layer on the first semiconductor layer and the metal particles; and
a fifth step of forming an electrode by processing the insulating layer, the first semiconductor layer, and the second semiconductor layer, wherein
the metal particles formed in the third step are composed of first metal particles formed on the first semiconductor layer and second metal particles formed on the insulating layer.

17. A method for manufacturing a semiconductor device, comprising:
a first step of forming an insulating layer on a channel region provided in a principal surface of a semiconductor substrate;
a second step of forming metal particles on the insulating layer;
a third step of forming a semiconductor layer on the insulating layer and the metal particles; and
a fourth step of forming an electrode by processing the insulating layer and the semiconductor layer, wherein a fifth step of forming a reaction layer on a surface of the metal particles by means of heat treatment is provided either or both before and after the fourth step.
